(19) United States
(12) Patent Application Publication
(10) Pub. No.: US 2002/0150130 A1
(43) Pub. Date: Oct. 17, 2002

(54) Tunable VCSEL assembly

(76) Inventors: Larry A. Coldren, Santa Barbara, CA (US); Eric Michael Hall, Santa Barbara, CA (US); Shigeru Nakagawa, Goleta, CA (US)

Correspondence Address: GATES & COOPER LLP, HOWARD HUGHES CENTER, 6701 CENTER DRIVE WEST, SUITE 1050, LOS ANGELES, CA, 90045, US

(21) Appl. No.: 09/836,451

(22) Filed: Apr. 16, 2001

(51) Int. Cl. H01S 3/10; H01S 5/00

(52) U.S. Cl. 372/20

(57) ABSTRACT

A tunable VCSEL assembly comprises a first substrate upon which a first epitaxial structure is formed, the first epitaxial structure having areas of different optical properties comprising a front mirror or reflector, an active region, a cavity and a rear surface. A back subassembly comprises a second substrate upon which a second epitaxial structure is formed, the second epitaxial structure having areas of different optical properties and comprising a back movable mirror or reflector having a forward surface. Bonding elements or materials are emplaced at selected spaced apart corresponding areas on each of the front subassembly and the back subassembly such that upon engagement, the front subassembly and the back subassembly are permanently bonded to one another. The front subassembly and the back subassembly are configured such that there is an elastic optically transparent gap between the front surface of the back movable mirror of the back subassembly and the rear surface of the front subassembly. Tuning the optical output wavelength of the VCSEL assembly in accordance with the present invention can be achieved by moving the mirror of the back subassembly to adjust the thickness of the elastic optically transparent gap between the front surface of the movable mirror and the rear surface of the front subassembly.

### BACKGROUND OF THE INVENTION

1. Field of the Invention

This invention relates to vertical cavity surface emitting lasers (“VCSELS”). More particularly, the present invention relates to VCSELs of the type desirable for use in certain optical communication networks. Even more particularly, the present invention relates to VCSELs having as its output a wavelength selected by the user.

2. Description of the Related Art

Optical communications systems promise to revolutionize the field of telecommunications. The advent of dense wave division multiplexing (DWDM) now allows tens and even hundreds of optical wavelengths to be multiplexed onto and transmitted along a single fiber. Lasers, and more particularly edge-emitting semiconductor lasers, provide the optical output of the current transmitters in DWDM systems. Each transmitter contains one laser that generates the optical output, of the transmitter. Control circuitry, optical beam conditioning, and other functions may be served by hardware and firmware included in the transmitter packaging. Each laser included in a transmitter located at a transmission point for a single fiber, or node, in a DWDM system emits light at a wavelength different from every other laser emitting light onto the fiber at that node. Each such wavelength is then combined via a wavelength multiplexer and transmitted down the strand of fiber. Therefore, if forty transmitters are used to simultaneously transmit light down a fiber, forty lasers, each emitting a distinct wavelength, are required.

In the first-generation DWDM systems, which are still in use, fixed wavelength edge-emitting lasers are incorporated in the system's transmitters. Fixed wavelength lasers each emit light at substantially only one wavelength. Therefore, if a DWDM system is designed for forty distinct channels, then forty different lasers, each having a different specification, are required to serve in the system's forty transmitters. Because any of the lasers could conceivably malfunction at any time, at least one spare transmitter that emits the same wavelength as a transmitter used in the system must be stored at the transmission site to serve as a replacement, or spare. Therefore, a great deal of capital expenditure is required simply to ensure that spare parts are readily available. Additionally, fixed wavelength transmitters do not readily enable systems that include real-time provisioning of bandwidth, wavelength-based switching schemes and hardware, as well as other features that would be available if the transmitters were themselves tunable across a wide variety of wavelengths.

In an effort to solve the problems associated with fixed wavelength lasers, tunable edge-emitting lasers have been developed. There are currently available narrowly-tunable and widely-tunable edge-emitting lasers. Narrowly-tunable lasers may be tuned across a few of the ITU (International Telecommunications Union) channels that may be used in a DWDM system and widely-tunable lasers may be tuned across many of the ITU channels, possibly including all or more of the channels used in any given DWDM system. By using either of these types of lasers, purchasers of DWDM systems can save money because they require far fewer spare transmitters than if their system used fixed wavelength lasers.

A number of methods and designs have been employed to produce tunable edge-emitting lasers. For narrowly-tunable lasers, these methods generally rely on tuning the index of refraction of the optical cavity. Such index adjustment may be induced by heating, the electro-optic effect, or carrier injection. Widely-tunable lasers may be tuned by similar methods or through utilizing an external cavity configuration. Although tunable edge-emitting lasers have been developed, they are more costly to manufacture, and have poorer coupling efficiencies than VCSELs.

As such, there has been a move to produce tunable VCSELs, which are generally simpler in their configuration, less costly to manufacture, and have higher coupling efficiencies than their edge-emitting counterparts. VCSELs are described in detail in, “Diode Lasers and Photonic Integrated Circuits,” Coldren, L.; Wiley, (1995), which is incorporated herein by reference. In a tunable VCSEL, the output wavelength is generally tuned by changing the length of the vertical cavity, effectively altering the output wavelength. Cavity length is changed through the use of a deformable or movable mirror which is moved using electrostatic attraction, or other forces, such as the VCSEL disclosed in U.S. Pat. No. 5,291,502 entitled Electrostatically tunable optical device and optical interconnect for processors, which issued to Pezeshki et al on Mar. 1, 1994.

Since that time, other improvements have been made relating to the configuration of the tunable VCSEL's movable mirror such as that disclosed in U.S. Pat. No. 5,629,951 entitled Electronically-Controlled Cantilever Apparatus for Continuous Tuning of the Resonance Wavelength of a Fabry-Perot Cavity which issued to Chang-Hasnain et al on May 13, 1997. However, none of the designs or methods currently known involve the production of a VCSEL having two separately produced subassemblies which are attached to each other using bonding or some other means, to form a tunable VCSEL assembly. Such a design would provide several advantages over the art and thus, what is needed in the art is a VCSEL formed from two separate subassemblies that are bonded to each other.

### BRIEF DESCRIPTION OF THE FIGURES

FIG. 1 is a cross sectional schematic view of a first preferred embodiment of a tunable VCSEL assembly in accordance with the present invention taken along L.

FIG. 2 is a cross sectional schematic view of the first preferred embodiment of a tunable VCSEL assembly in accordance with the present invention taken along W.

FIG. 3 is a disassembled cross sectional schematic view of the first preferred embodiment of a tunable VCSEL assembly in accordance with the present invention taken along L.

FIG. 4 is a disassembled cross sectional schematic view of first preferred embodiment of a tunable VCSEL assembly in accordance with the present invention taken along W.

FIG. 5 is a rear schematic view of a first preferred front subassembly in accordance with the present invention.

FIG. 6 is a front schematic view of a first preferred back subassembly in accordance with the present invention.

FIG. 7 is a cross sectional schematic view of a second preferred embodiment of a tunable VCSEL assembly in accordance with the present invention taken along L.

FIG. 8 is a cross sectional schematic view of a second preferred embodiment of a back subassembly in accordance with the present invention.

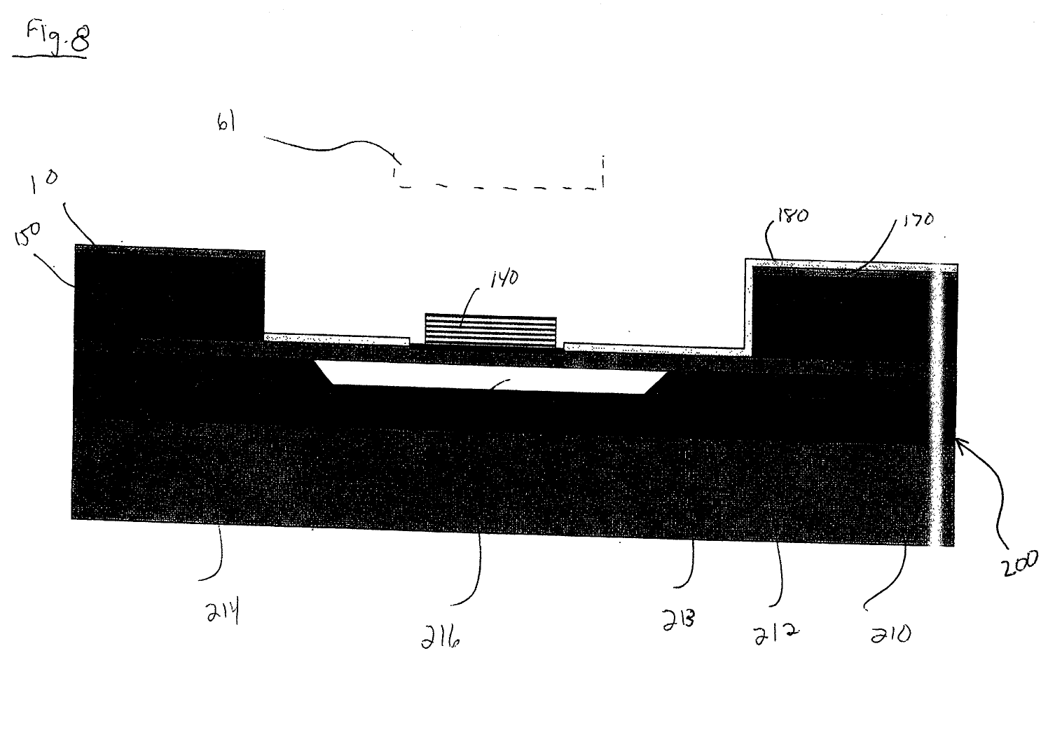

FIG. 9 is a cross sectional schematic view of a third preferred embodiment of a back subassembly in accordance with the present invention.

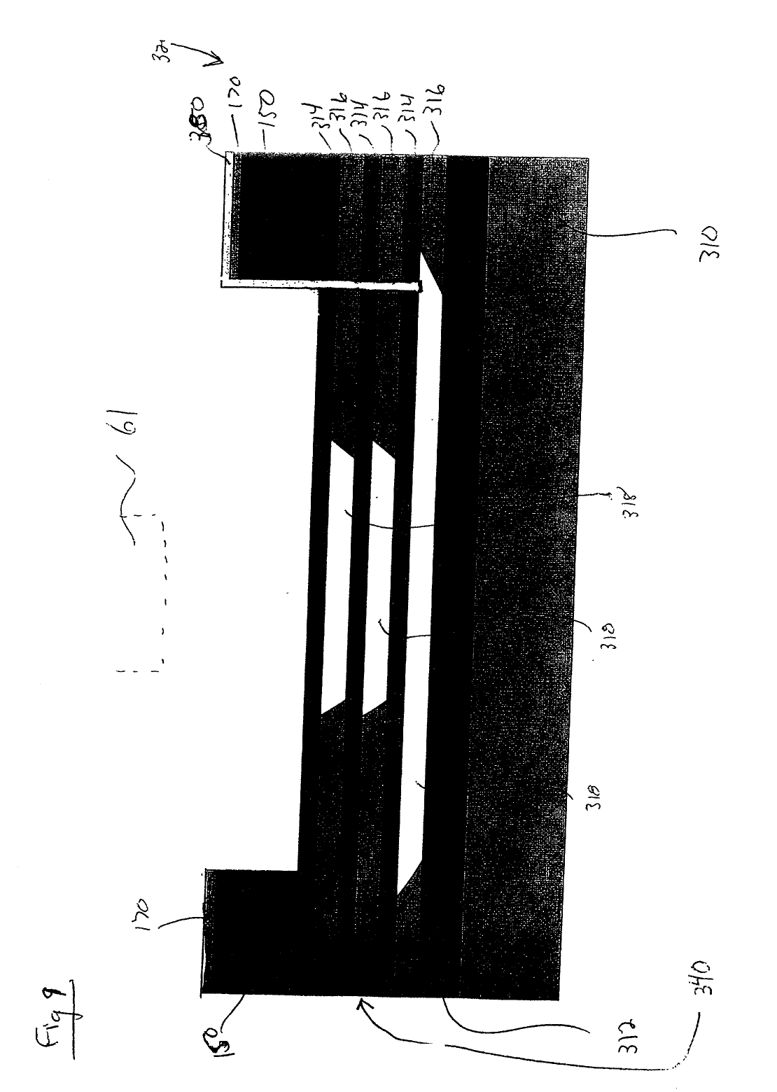

### SUMMARY OF THE INVENTION

Accordingly, an object of the present invention is to provide an improved tunable VCSEL assembly.

Another object of the present invention is to provide a tunable VCSEL assembly that is comprised of two attached subassemblies.

Another object of the present invention is to provide a tunable VCSEL assembly that is comprised of two attached subassemblies that are bonded to each other.

Another object of the present invention is to provide a tunable VCSEL assembly that is comprised of two subassemblies or portions that are flip-chip bonded to each other.

A further object of the present invention is to provide a tunable VCSEL assembly fabricated upon at least two substrates.

An additional object of the present invention is to provide a tunable VCSEL assembly fabricated on at least two substrates of differing material.

Another object of the present invention is to provide a tunable VCSEL assembly fabricated upon at least two substrates wherein at least one of the at least two substrates is a semiconductor.

Another object of the present invention is to provide a tunable VCSEL assembly, the production of which requires a simplified fabrication methodology.

A further object of the present invention is to provide a tunable VCSEL assembly that has a wide tuning range and is fabricated on two substrates of differing materials.

Another object of the present invention is to provide a tunable VCSEL assembly that can be extended to large arrays of tunable VCSELS.

A further object of the present invention is to provide a tunable VCSEL assembly that has an easily created optical aperture.

A further object of the present invention is to provide a tunable VCSEL assembly that has a mirror formed from substrate material.

These and other objects of the present invention are achieved in a tunable VCSEL assembly that comprises a front subassembly and a back subassembly wherein each of the front subassembly and the back subassembly are formed on a separate substrate. The front subassembly and the back subassembly are attached to each other, preferably permanently, to form a tunable VCSEL assembly in accordance with the present invention. This attachment can be done using conventional flip-chip bonding equipment.

In such a laser assembly, each of the front subassembly and back subassembly may be separately optimized and fabricated using existing well-established technology thereby increasing product yield and performance while reducing production costs. Such a VCSEL assembly is simpler to manufacture than widely-tunable edge-emitting diode lasers, and other tunable VCSELs.

The front subassembly comprises a first substrate upon which a first structure is formed, the first structure having areas of different optical properties comprising a front mirror or reflector, an active region, a cavity and a rear surface. By ending the growth of the front subassembly section after the cavity, an aperture for optical and current confinement can be easily defined. For example, an optical aperture may be defined by an index step into the cavity itself, and an electrical aperture can be defined easily by implanting to disorder a tunnel junction that is preferably included in the front subassembly. Additionally, the front subassembly may have a partial back mirror included therein, the rear surface of which may define or partially define the rear surface of the front subassembly.

The back subassembly comprises a second substrate upon which a second structure is formed, the second structure having areas of different optical properties and comprising a back movable mirror or reflector having a forward surface. The back subassembly may be separately optimized and mass-produced from a front subassembly. The back subassembly may be mass-produced, for example, from Si in a Si-MEMS foundry, or from other well-known materials and processes. Additionally, the back movable mirror may be formed from materials that are not lattice matched to the front subassembly substrate, which would be required if the VCSEL assembly were to be monolithically produced upon a single substrate.

Bonding elements or materials are emplaced at selected spaced apart corresponding areas on each of the front subassembly and the back subassembly such that upon engagement, the front subassembly and the back subassembly are attached and preferably permanently bonded to one another. The front subassembly and the back subassembly are configured such that there is a variable optically transparent gap between the forward surface of the back movable mirror of the back subassembly and the rear surface of the front subassembly.

Tuning the optical output wavelength of the VCSEL assembly in accordance with the present invention can be achieved by moving the mirror of the back subassembly to adjust the thickness of the variable optically transparent gap between the forward surface of the back movable mirror and the rear surface of the front subassembly.

Other features and advantages of the invention either will become apparent or will be described in connection with the following, more detailed description of the invention.

### DETAILED DESCRIPTION

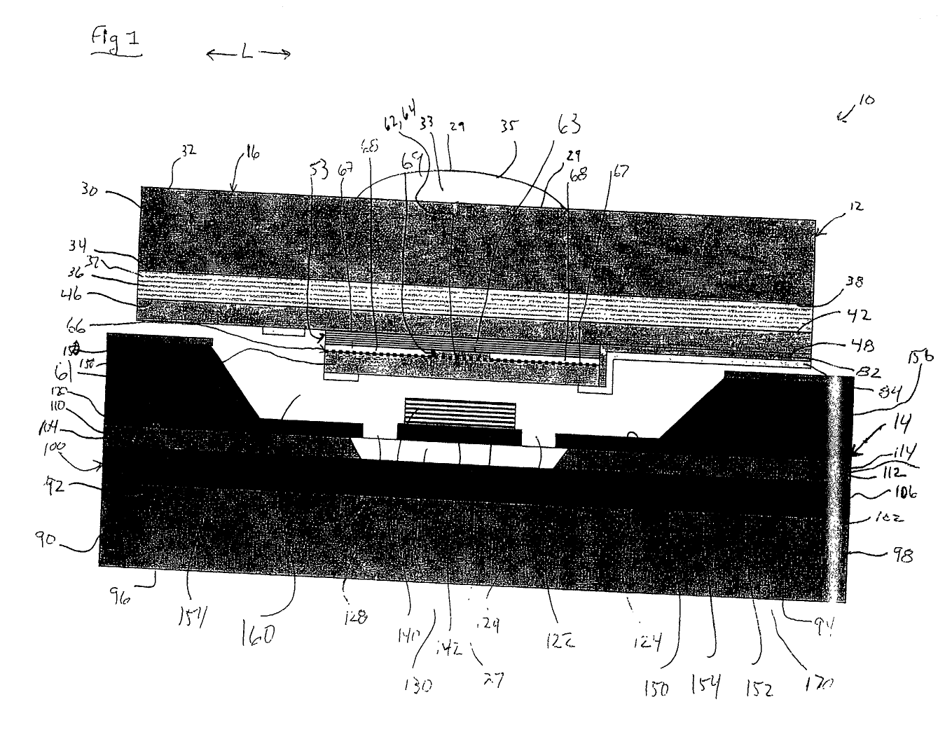

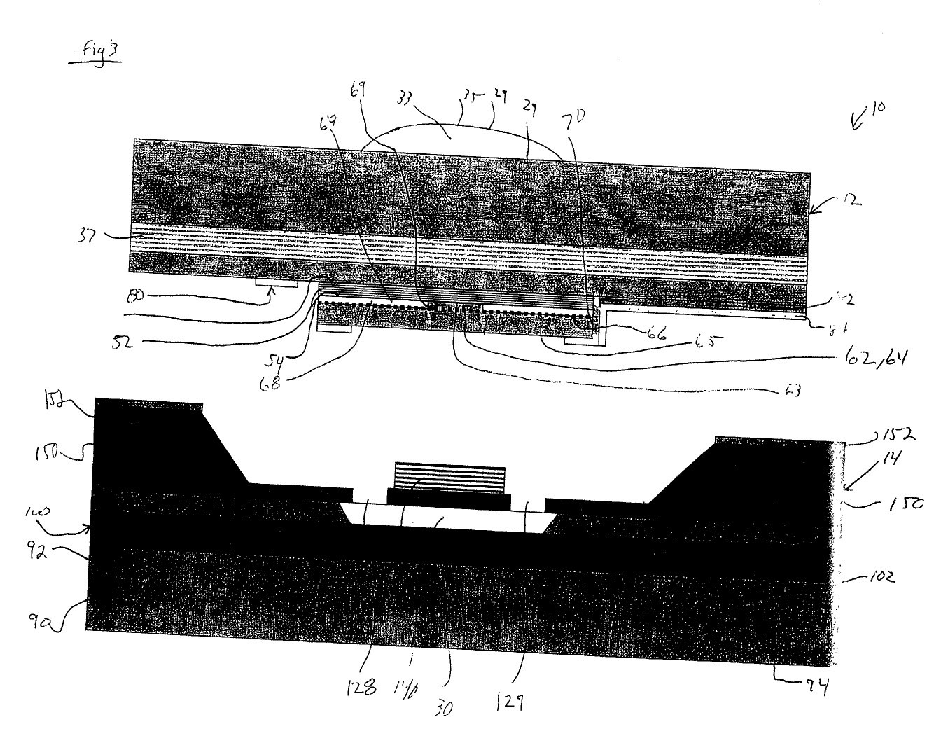

Referring now generally to FIGS. 1-4 of the accompanying drawings, a tunable VCSEL assembly, generally denoted at 10, in accordance with the present invention provides for the process of generation and output of a substantially monochromatic light wave at one of a plurality of user selectable wavelengths. VCSEL assembly 10 generally includes a front subassembly 12 and a back subassembly 14. Each of the front subassembly 12 and the back subassembly 14 is separately fabricated on a substrate using compatible photonic integrated circuit (IC) technology and micro electromechanical systems (MEMS) technology for all the elements epitaxially grown, etched, assembled, deposited, or the like, upon the associated substrate. Each of the methods listed hereinabove, including epitaxial growth, such as Molecular Beam Epitaxy (MBE) and Metal Organic Chemical Vapor Deposition (MOCVD), wet and dry etching, deposition, bonding, and other processing technologies in the art, as well as the materials and equipment required for each said process are well known to those skilled in the art, and as such, shall not be discussed further herein.

The front subassembly 12 and back subassembly 14 are each fabricated using a separate substrate and then subsequently bonded to one another as described in detail hereinbelow. Therefore, the materials of the front subassembly 12 and the back subassembly 14 do not have to be lattice matched to each other, nor do they have to have precisely matching coefficients of thermal expansion which effectively simplifies the production process and improves device yields when compared to monolithically produced tunable VCSELs.

In a preferred embodiment, and as shown in FIGS. 1-4, the front subassembly 12 of the tunable VCSEL assembly 10 has a front substrate layer 30 having a forward surface 32 and a rear surface 34. The forward surface 32 of the front substrate layer 30, is substantially planar in its configuration, and may serve as the front face 16 of the tunable VCSEL assembly 10. An anti-reflective coating 29 is preferably applied to the forward surface 32 of the front substrate layer 30. The anti-reflective (AR) coating substantially reduces any internal reflections in the tunable VCSEL assembly 10, and thereby aids in the proficient functioning thereof. Such AR coatings are well known by those skilled in the art.

Additionally, the forward surface 32 of the front substrate layer 30 may, preferably, have a micro-lens 33 etched therein or formed thereupon. A micro-lens serves to collimate the light beam, aiding in increasing transmission distances. The micro-lens 33 provides a substantially convex surface 35 preferably positioned centrally to the forward surface 32 or preferably positioned collinear with an optical aperture 62 described in detail hereinbelow. Collimating lenses are well know to those skilled in the art and the process of etching, growing or depositing a portion of the forward surface 32 to produce such a collimating lens, although novel, may be accomplished by those skilled in the art without undue experimentation.

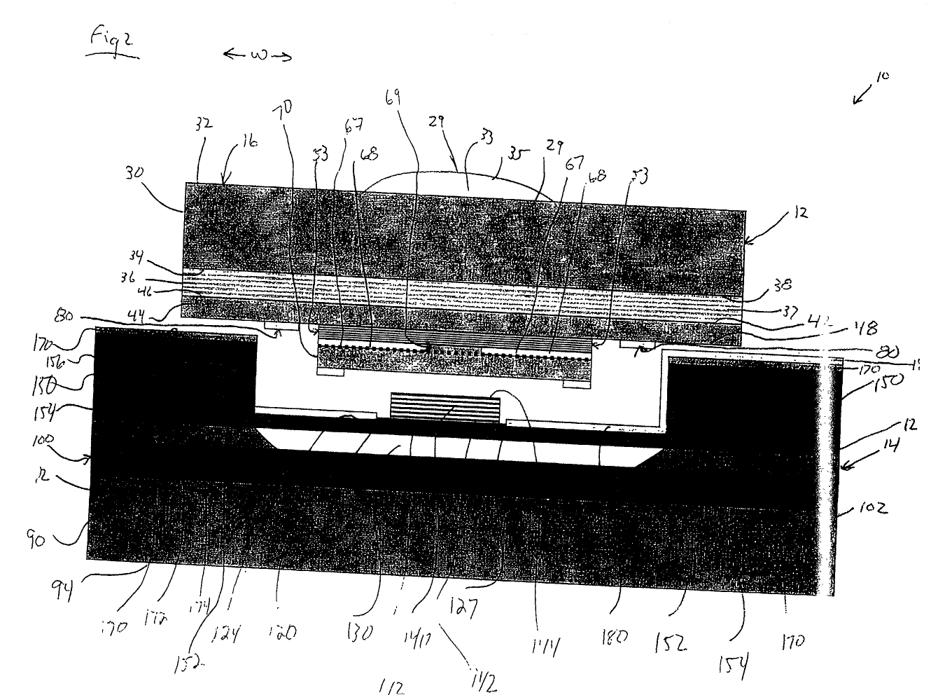

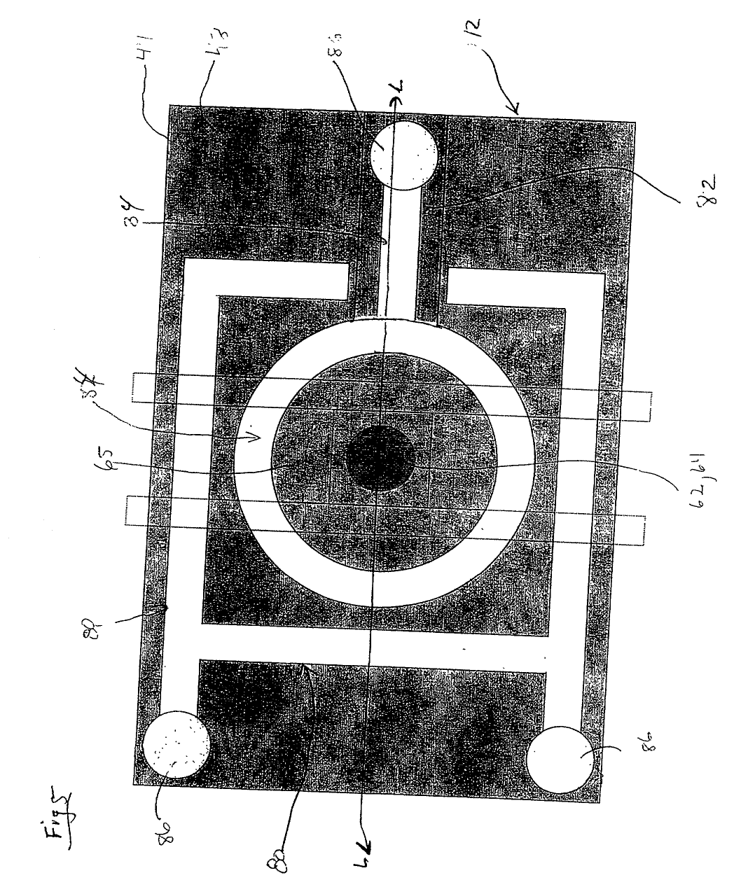

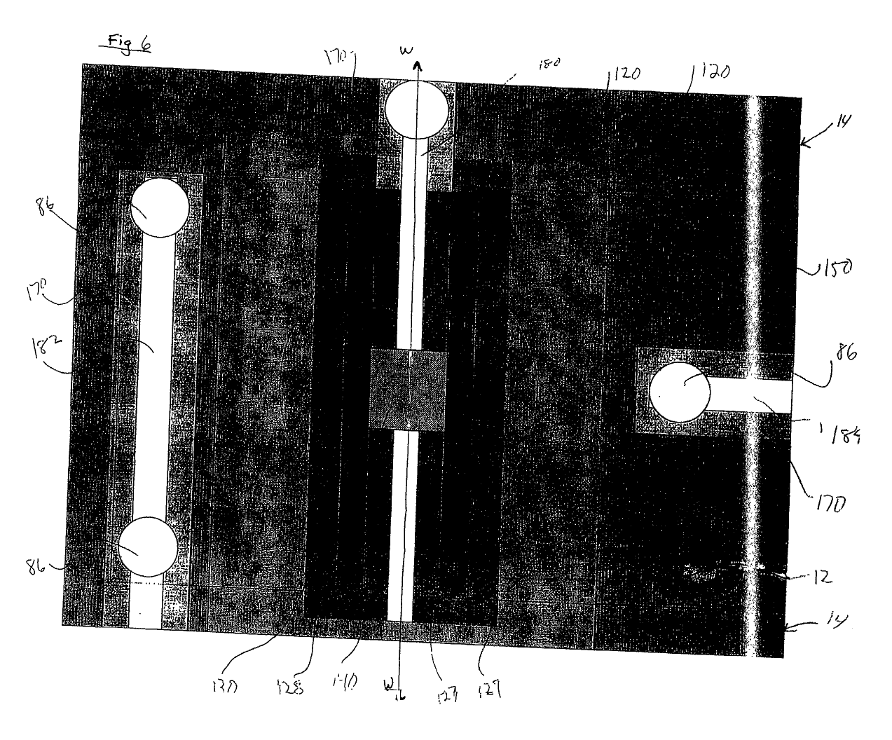

Unless otherwise defined, the term “forward surface”, when used to define or more fully detail an aspect of a layer described herein, is descriptive of that generally substantially planar surface of the layer aligned in a substantially parallel relation with the face 16 and positioned proximal the face 16 in relation to all other surfaces of the associated layer. Unless otherwise defined, the term “rear surface”, when used to define or more fully detail an aspect of a layer described herein, is descriptive of that generally substantially planar surface of the layer aligned in a substantially parallel relation with the face 16 and positioned distal the face 16 in relation to all other surfaces of the associated layer. Each “forward surface” and “rear surface” defined herein has a length equal to the distance the surface extends in a direction parallel to L (shown in FIGS. 1 and 5) and a width defined as the distance the surface extends in a direction parallel to W (shown in FIGS. 2 and 6).

The front substrate layer 30 is preferably comprised of indium phosphide (InP), although it may also be formed from a material having similar properties, such as AlInGaAs, InGaAsP, or other materials similar in behavior that are known to those skilled in the art. It is to be appreciated by those skilled in the art that currently InP provides very good performance and stability and therefore the examples provided throughout shall utilize InP in the front substrate layer 30.

The front substrate layer 30 may be purchased from companies producing InP substrates such as Sumitomo Electric Industries located in San Francisco, Calif., USA; Groupe Arnaud Electronics located in Paris, France; InPACT, located in Pombliere, Moutiers, France, or a host of other well known companies producing InP substrates that may be used as the front substrate layer 30. InP substrates are well known in the art, as are the materials and processes required to produce the InP substrates, and as such, these materials and processes shall not be further described herein.

The front substrate layer 30 has a depth defined by the distance the front substrate layer 30 extends between the forward surface 32 and the rear surface 34. Preferably, the depth of the front substrate layer 30 should be between about 300 μm and about 500 μm, although it may range from 100 μm to 800 μm. However, the area of the front substrate layer 30 that may have the micro-lens 33 disposed thereat, may actually be etched away to have a much smaller depth, including a depth approaching 0 μm. In this case, there would be no micro-lens 33 included in the device, however, a micro-lens 33 may be included given sufficient depth remaining to support the formation or deposition of a lens thereat.

The rear surface 34 of the front substrate layer 30 contiguously abuts a front mirror 36 at the front mirror's 36 forward surface 38. The front mirror 36 is preferably comprised of a distributed Bragg reflector (DBR) 37 formed from alternating layers of AlGaAsSb and AlAsSb, such that each alternating layer has a different index of refraction from those layers adjacent thereto. The DBR 37 is preferably formed from at least about twenty (20) alternating layers of these materials to provide a fairly wide bandwidth across which the front mirror 36 will have the preferred reflectivity set out hereinbelow. The preferred DBR 37 may have as few as about fifteen (15) layers and function so as to provide for operation of the tunable VCSEL assembly 10.

Alternatively, the DBR 37 may be comprised of alternating layers of AlGaAsSb and AlGaAsSb wherein each of the layers differs in the relative proportions of Al or Ga or a combination thereof, such that alternating layers have different indexes of refraction. The DBR 37 may also be formed from some other at least two materials, wherein each of the at least two materials is lattice matched to the front substrate layer 30, each one of the at least two materials has a different index of refraction, an where the DBR may be formed with as few layers as possible. Such DBR mirrors may include AlGaInAs or InGaAsP which are well known in the art, and the materials required to produce such a mirror or the process for depositing those materials shall not be further described herein.

The front mirror 36 has a rear surface 42 that contiguously abuts an n-type front contact layer 44 at the front contact layer's 44 forward surface 46. The front mirror 36 should preferably reflect between about 97% and 99.5% of the light traveling from the direction of the front contact layer 44. The front mirror 36 should preferably have a bandwidth of at least about 40 nm (nanometers) wherein the reflectivity of the front mirror 36 with respect to light traveling from the direction of the front contact layer 44 ranges very little. However, a bandwidth of at least about 20 nm may suffice to provide somewhat wider tunability than is available with narrowly-tunable lasers.

The depth of the front mirror 36 will vary depending upon the materials selected to produce the mirror. The configuration and proportions of the materials selected to produce a semi-reflective mirror having the reflectivity and bandwidth set out hereinabove is well known by those skilled in the art.

The front contact layer 44 is preferably formed from a material that has a relatively high thermal conductivity and that is lattice matched to the front substrate layer 30. Such a material will be well known to those skilled in the art and shall not be discussed further herein. As such, if the front substrate layer 30 is InP, the front contact layer 44 should be formed from InP that is doped to be n-type.

The front contact layer 44 extends between its forward surface 46 and a rear surface 48 thereof. The front contact layer 44 is doped using processes and materials that are well known to those skilled in the art. And all references to the doping of materials hereinbelow are also well known to those skilled in the art and shall require no further discussion.

A portion of the rear surface 48 of the front contact layer 44 abuts a forward surface 50 of an active region layer 52. The active region layer 52 has preferably a cylindrical form, although other forms or shapes known to those skilled in the art may suffice. The active region layer 52 extends from its forward surface 50 towards and terminating at a rear surface 54 thereby defining an outer surface 53 circumferentially surrounding the active region layer 52. The forward surface 50 and the rear surface 54 should both be shorter in length and shorter in width than the forward surface 38 and the rear surface 42 of the front mirror 36 and the front contact layer 44. The active region layer 52 is preferably formed from materials that are latticed matched to the front contact layer 44 which is in turn, as set out hereinabove, lattice matched to the front mirror 36 and generally lattice matched to the front substrate layer 30. For example, and as described in the preferred embodiment, if the front substrate layer 30 and the front contact layer 44 are each formed from InP, and the front mirror 36 is a DBR 37 comprised of alternating layers of AlGaAsSb and AlAsSb, which is lattice matched to the InP of front substrate layer 30 and the front contact layer 44, then an appropriate material to serve as the active region layer 52 would be AlInGaAs which is lattice matched to the front contact layer 44, the front mirror 36 and the front substrate layer 30.

As shown in FIGS. 1-4, a back contact layer 61 is preferably formed from the same material as the front contact layer 44, is preferably shaped substantially similarly to the active region layer 52 and extends from a forward surface 63 abutting the rear surface 54 of the active region layer 52 to a rear surface 65 thereof thereby defining an outer surface 70 circumferentially surrounding the back contact layer 61. Alternatively, the back contact layer 61 may be formed from a material that is lattice matched to the front contact layer. If the front contact layer 44 is formed from InP, then the back contact layer 61 may be formed from AlGaInAs, InGaAsP, or AlGaAsSb, although these are not as thermally or electrically conductive as InP.

The back contact layer 61 may be formed of p-type material for hole injection, however n-type material provides for lower optical loss and higher electrical conductivity, and therefore the back contact layer 61 is preferably doped as n-type throughout the layer. However, in using n-type material, a tunnel junction 66, denoted by the dotted line extending from the outer surface 70 in a plane parallel to the forward surface 63 of the back contact layer 61, is preferably included to improve performance of the assembly 10. A tunnel junction is an area where there exists a highly doped n-type layer abutting a highly doped p-type layer. In this case, of the two highly doped layers, the highly doped player is proximate the forward surface 63 with respect to the highly doped n-layer.

The tunnel junction 66 minimizes the amount of p-type material that is required to enable current flow into the active region layer 52. Minimizing p-type material is advantageous because it has higher optical absorption than the n-type of the same material. Therefore, the tunnel junction 66 aids in maximizing optical transmission through the back contact layer 61 and provides for lower series resistance by allowing the use of primarily n-type material in the back contact layer 61.

The back contact layer 61 preferably has an optical aperture 62 and an electrical aperture 64 formed therethrough, although said optical aperture 62 and said electrical aperture 64 may not be absolutely necessary to practice the invention they do provide improved performance thereof. As depicted in FIG. 1, material at the forward surface 63 of the back contact layer 61 is etched away, or undergoes some other well-known process to remove material or to render it substantially electrically non-conducting, such as through the implantation of dopants including carbon or oxygen, thus defining a non-conducting zone 68. This essentially defines the electrical aperture 64 as the area surrounded by the non-conducting zone 68.

Additionally, a portion of the back contact layer may serve as an optical inhibitor 67. The optical inhibitor 67 may be made substantially optically opaque, such as through oxidation, or by partially implanting the material with dopants, such as carbon or oxygen. Alternatively, the optical inhibitor 67 may be formed to have an optical length that differs from the optical length of the remainder of back contact layer 61, thus defining the optical aperture 62.

In the preferred embodiment, the non-conducting zone 68 and the optical inhibitor 67 each extend inwardly from the outer surface 70 and terminates at and circumferentially surround the optical aperture 62 and the electrical aperture 64. Although the preferred embodiment, as described in more detail hereinbelow depicts the optical aperture 62 and the electrical aperture 64 formed in substantially the same material at the same locations, each may be decoupled and formed such that that are preferably somewhat co-linear, but not necessarily formed at the same location.

The optical aperture 62 and the electrical aperture 64 preferably each have a substantially cylindrical configuration and extend from the forward surface 63 of the back contact layer 61 to the tunnel junction 66 in the back contact layer 61. Because the substantially non conducting zone 68 serves as an electrical insulator and because the optical inhibitor 67 has an index of refraction far different from both the active region layer 52 and the rest of the material in the back contact layer 61, electrical charge will tend to flow through the electrical aperture 64 and light will propagate substantially only through the optical aperture 62. This will be discussed further hereinbelow.

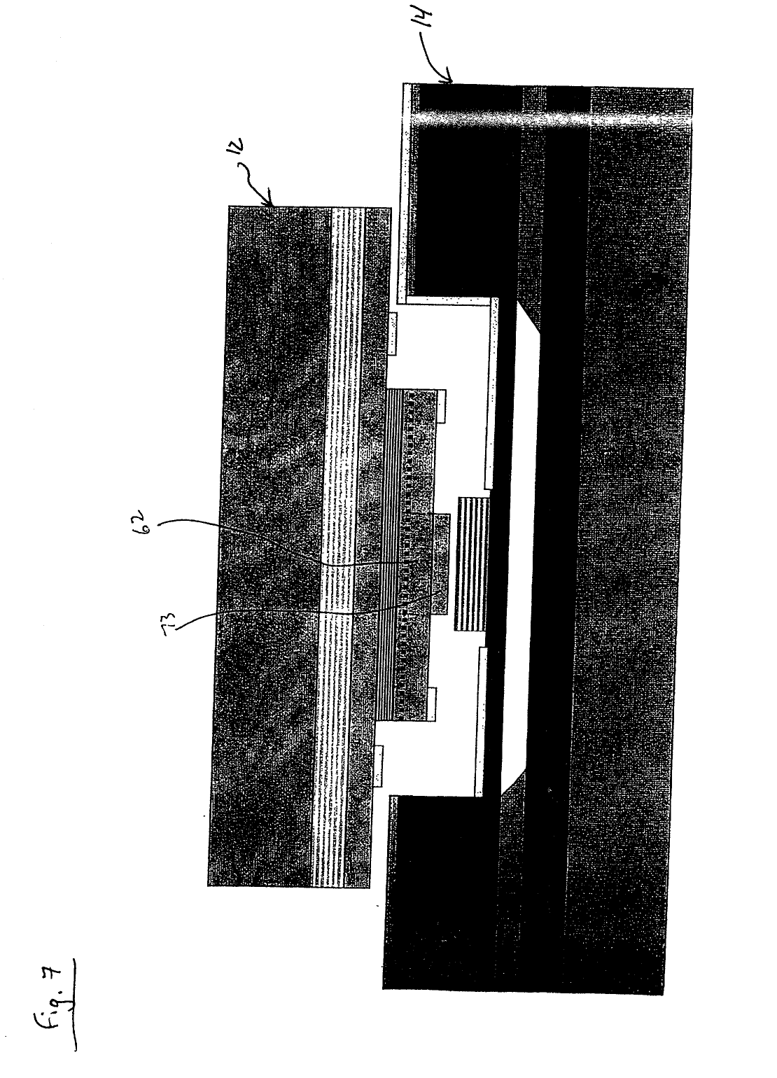

Additionally, as depicted in FIG. 7, an altered depth section 73 may be formed at the rear surface 65 of the back contact layer 61. Essentially, the altered depth section 73 alters the optical length of the back contact layer 61 thereat, thereby defining the optical aperture 62. The altered depth section 73 may be preferably formed from the same material as the back contact layer 61, for example an index step disposed thereat, or alternatively, it may be formed from etching material thereat. The inclusion of the altered depth section 73 may improve the laser 10 performance by allowing the front subassembly 12 to be configured to emit light through the rear surface 65 of the back contact layer 61 only through the altered depth section 73.

Through the inclusion of the altered depth section 73, the optical inhibitor 67 and/or the substantially non conducting zone 68 may not be included and the tunable VCSEL 10 will function well given that the optical length of the optical aperture 62 at the altered depth section 73 differs from the material thereby surrounding it. Alternatively, the altered depth section 73 may not be included if the non-conducting zone 68 and the optical inhibitor 67 are both included.

The altered depth section 73 may also serve as a microlens as well. In this case the altered depth section 73 will preferably have a substantially convex, or cone-shaped configuration extending and tapering from the rear surface 65 of the back contact layer 61 as it extends towards the back subassembly 14. The microlens in this instance focuses or collimates the beam of light increasing output power and improving beam shape.

The area comprising the tunnel junction 66, the optical aperture 62 and the electrical aperture 64, and the non-conducting zone 68 is additionally referred to herein as the funnel area 69. The funnel area 69, although preferably located as disclosed hereinabove, may also be positioned intermediately abutting the rear surface 48 of the front contact layer 44 and the forward surface 50 of the active region layer 52. To effectuate this positioning of the funnel area 69, each of the layers or elements of the funnel area 69 must be positionally reversed. As such, the tunnel junction 66 would abut the rear surface 48 of the front contact layer 44 and so on. Additionally, current will flow in a direction opposite of flow in the preferred embodiment.

As best shown in FIG. 5 and also shown in part in FIGS. 1-4, a front electrode 80 is deposited upon, mounted to or bonded to the rear surface 48 of the front contact layer 44. Methods for deposition of such electrodes, as well as methods of bonding, including epoxying and soldering are well known in the art and as such will not be discussed further herein. The front electrode 80 is preferably formed from some well conducting elastic material such as gold (Au), nickel (Ni) or some other some other material used as an electrode in semiconductors such as TiPtAu, or AgGeNi. The front electrode 80 substantially surrounds the area of the rear surface 48 of the front contact layer 44 that has abutted thereto the forward surface 50 of the active region layer 52.

An insulating layer 82 abuts and extends along a portion of the rear surface 48 of the front contact layer 44. The insulating layer 82 extends along line L and then along the outer surface 53 of the active region layer 52 and the outer surface 70 of the back contact layer 61 terminating at the rear surface 65 of the back contact layer 61. The insulating layer 82 may be formed from a dielectric, the same material as the front contact layer 61 further being implanted with a material such as carbon or the like or some other non conducting material well known to those skilled in the art for such a purpose.

A back electrode 84 abuts and extends the length of the insulating layer 82. The back electrode 84 additionally extends along the rear surface 65 of the back contact layer 61 extending inwardly from the outer surface 70 thereof and therefor circumferentially abutting the rear surface 65 of the back contact layer 61. The back electrode is preferably formed from the same material as the front electrode 80.

When a voltage is applied across the front electrode 80 and the back electrode 84, current tends to flow from the back electrode 84 laterally along the back contact layer 61, through the tunnel junction 66 and the electrical aperture 64, diffusing along the active region towards the front electrode 80. The insulating layer 82 ensures that there is no current leakage to the active region 52 and the front contact layer 44 which will result in the device not functioning properly.

As shown in FIG. 5, bump bonds 86 are bonded to or mounted to the front electrode 80 and the back electrode 84. In the preferred embodiment, two bump bonds 86 contact the front electrode 80 at two spaced apart positions and a single bump bond 86 contacts the back electrode 84. The bump bonds 86 are preferably formed from a highly conductive elastic material such as gold or indium, or some other conductive elastic material known those skilled in the art for such a purpose.

As shown in FIGS. 1-4 and 6, a first preferred embodiment of the back subassembly 14 generally includes a back substrate layer 90 having a forward surface 92 and a rear surface 94. The rear surface 92 of the back substrate layer 90, is substantially planar in its configuration, and serves as the back face 96 of the tunable VCSEL assembly 10.

The back substrate layer 90 is preferably comprised of the first layer of a silicon on insulator (SOI), although it may also be formed from a different material having similar properties, such as a substrate having a first layer of GaAs having alternating layers of GaAs and GaAlAs grown thereupon, a dielectric with appropriate metallization, Al₂O₃, or some other material that is easy to use for a purpose such as this and is well known to those skilled in the art. The back substrate layer 90 has an outer surface 98 defined by the periphery of the back substrate layer 90 as it extends between its forward surface 92 and its rear surface 94. The back substrate layer 90 may be purchased from companies producing SOI substrates or other similar substrates such as Wacker Siltronic, having an office in Portland, Oreg., USA, Unisil, having a place of business at 2400 Walsh Avenue, Santa Clara, Calif. 95051, USA, or a host of other well known companies producing SOI substrates that may be used as the back substrate layer 90.

SOI substrates are essentially substrates having layers of two lattice-matched materials that are separated by a dielectric, or a third, lattice matched material. SOI substrates and GOI substrates are well known in the art, as are the materials and processes required to produce the SOI substrates, and as such, these materials and processes shall not be further described herein.

The forward surface 92 of the back substrate layer 90 contiguously abuts a conductive back contact layer 100 at the back contact layer's rear surface 102. The back contact layer 100 is formed from a material that has substantially the same coefficient of thermal expansion as the back substrate layer 90. As such, if the back substrate layer 90 is formed from Si, as in the preferred embodiment, then the back contact layer 100 should preferably be formed from Si that is doped to be n-type. The back contact layer 100 extends between its rear surface 102 and a forward surface 104 thereof, the periphery of which defines an outer surface thereof 106. The back contact layer 100 is doped using processes and materials that are well known to those skilled in the art. All references to various materials and their doping, deposition, etching, and growth hereinbelow are also well known to those skilled in the art and shall require no further discussion.

The forward surface 104 of the back contact layer 100 abuts a rear surface 112 of a sacrificial layer 110. The sacrificial layer 110 extends from its rear surface 112 towards and terminating at a forward surface 114 thereby defining an outer surface 116 peripherally surrounding the sacrificial layer 110. The sacrificial layer 110 is preferably formed from materials that are matched to the coefficient of thermal expansion of the back contact layer 100 which is in turn, as set out hereinabove, matched to the coefficient of thermal expansion of the back substrate layer 90. As such, in the first preferred embodiment thereof, the sacrificial layer 110 is preferably formed from silicon dioxide (SiO₂). If the substrate layer is GaAs, the sacrificial layer 110 would preferably be GaAlAs or an oxide of GaAlAs.

A front contact layer 120 is formed from the same material as the back contact layer 100, and extends from a rear surface 122 abutting the forward surface 114 of the oxide layer 110 to a forward surface 124 thereof thereby defining an outer surface 126 peripherally surrounding the front contact layer 120. The front contact layer 120 is illustratively doped as n-type throughout the layer and has material etched away to define two slotted apertures 128, 129 therein, each slot extending between the forward surface 124 and the rear surface 122 of the front contact layer 120. A central bar 127 extends in the same direction and intermediate the two apertures 128, 129

Material in the sacrificial layer 110 is etched through a process that is well known to those skilled in the art to remove substantially all of the oxide layer 110 that lies beneath the apertures 128, 129 and the central bar 127. Material in the oxide layer 110 is removed in the area laterally extending beyond the periphery of the apertures 128, 129 but less than the width of the oxide layer 110 as taken along line W to define the gap region 130. The gap region 130 allows flexure of the central bar 127 in the direction of the back surface 96 of the laser assembly 10. The purpose of this flexure shall be discussed hereinbelow.

A back mirror 140 is formed, mounted or bonded to the forward surface 124 of the front contact layer 120. The back mirror 140 has a rear surface 142 that contiguously abuts the front contact layer 120 at the front contact layer's forward surface 124. The rear surface 142 may be a layer of the DBR as disclosed hereinbelow, or the rear surface 142 may be a highly reflective material such as gold, aluminum, silver or the like, that may be deposited upon or bonded to the forward surface 124 of the contact layer 120. The back mirror 140 should preferably reflect about one hundred percent (100%) of the light traveling from the direction of the front subassembly 12 striking a forward surface 144 thereof. The back mirror 120 should have a bandwidth substantially similar to that of the front mirror 36. The back mirror 120 should preferably have a width and a length each at least greater than the width and the length of, or a circumference greater than the circumference (if cylindrical) of, the smaller of the optical aperture 62 or the electrical aperture 64.

By ensuring all of the light striking the back mirror 120 does so well within the periphery thereof, scattering loss is substantially reduced which results in increased efficiencies of the tunable laser assembly 10. The depth of the back mirror 140 will vary depending upon the materials selected to produce the mirror. The back mirror 140 is preferably formed from alternating layers of SiO₂ and TiO₂, but may also be formed from alternating layers of gallium arsenide (GaAs) and aluminum arsenide (AlAs), or from other alternating materials that form a DBR, or from a single material that is about one hundred percent reflective. The configuration and proportions of the materials selected to produce a substantially fully reflective mirror having the reflectivity and bandwidth set out hereinabove is well known by those skilled in the art. The gap region 130 is preferably formed after the back mirror 140 is atop the front contact layer 120.

A frame layer 150 is formed atop the front contact layer 120 in order to properly space the front subassembly 12 from the back subassembly 14. It may be deposited or grown insulating material, such as SiO₂, or if Si is used for the back substrate layer 90, then it may be Si. In the preferred embodiment, however, it has a type the opposite of the front contact layer 120. Therefore, if the front contact layer 120 is n-type, the frame layer 150 may be p-type. The frame layer 150 has a forward surface 152 and a rear surface 154 and is mounted atop the forward surface 124 of the contact layer 120 at its rear surface 154. The frame layer 150 extends from its forward surface 152 to its rear surface 154 and has an outer surface 156 defined thereby. An area central to the frame layer 150 and extending from the forward surface 152 to the rear surface 154 thereof is etched away, prior to growth or placement of the back mirror 140 to define a cavity 160. The cavity 160 is configured to house the back contact layer 61 of the front subassembly 12 therein and to provide to a gap between the rear surface 65 of the back contact layer 61 and the forward surface 152 of the back mirror 150.

An insulating layer 170 is formed atop the frame layer 150. The insulating layer 170 has a forward surface 172 and a rear surface 174. The rear surface 174 of the insulating layer 170 abuts the forward surface 152 of the frame layer 150. An area central to the insulating layer 170 and extending from the forward surface 172 to the rear surface 174 thereof is etched away, prior to etching the frame layer 150. The cross sectional area etched from the insulating layer 170 is preferably substantially similar to the cross sectional area etched away at the forward surface 152 of the frame layer.

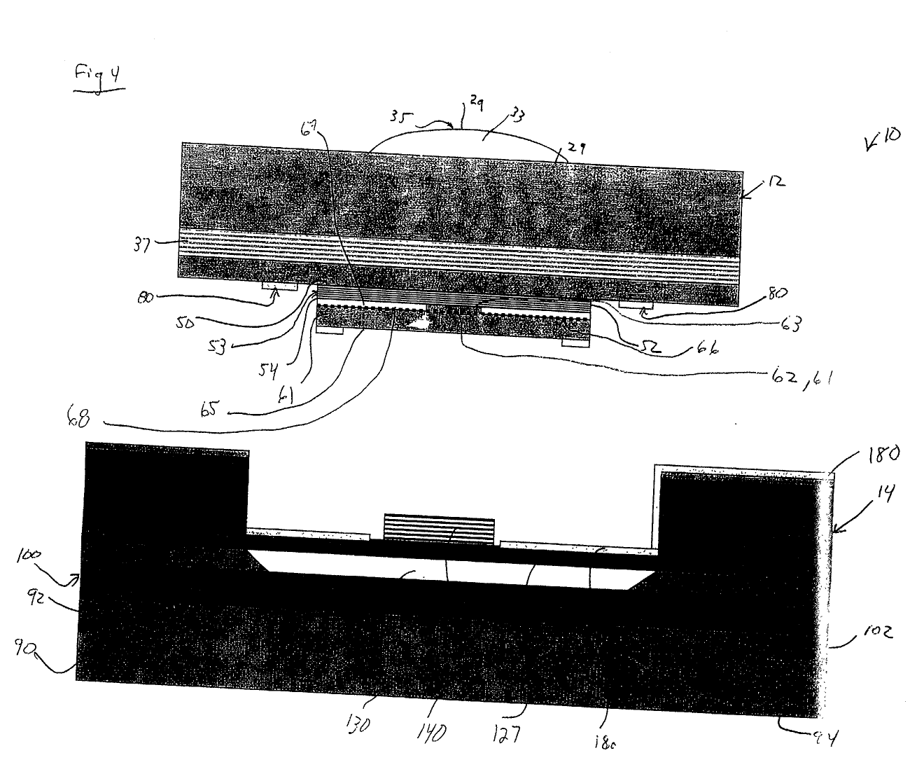

As shown in FIG. 6 and partly in FIGS. 2 and 4, a back mirror electrode 180 continuously extends parallel to W, from atop the insulating layer 170, down into the cavity and runs atop the forward surface 124 of the front contact layer 120 and extends between and in parallel to the slotted apertures 128, 129. The back mirror electrode is preferably deposited prior to mounting the back mirror 140, such that the back mirror sits atop the back mirror electrode 180. Additionally, the back mirror electrode 180 is positioned outside of the footprint of the front assembly 12, as shown in shadow in FIG. 6.

A front electrode bonding element 182 is seated or deposited atop the insulating layer 170 and a back electrode bonding element 184 is seated or deposited atop the insulating layer 170. The front electrode bonding element 182 has at least one, and in the preferred embodiment, two bump bonds 86 emplaced and mounted thereupon, and such bump bonds 86 are in correspondence with the at least one, and in the preferred embodiment, two bump bonds 86 positioned upon the front electrode 80. The back electrode bonding element 184 has at least one bump bond 86 emplaced and mounted thereupon, and such bump bond 86 is in correspondence with the bump bond 86 positioned upon the back electrode 84. Each of the front electrode bonding element 182 and the back electrode bonding element 184 extend to an edge of the back subassembly 14 to provide contacts for assemblage with control hardware or packaging within a package such as a butterfly package, which is well known to those skilled in the art, or some other well known package.

To permanently assemble the tunable laser assembly 10, the front subassembly 12 is positioned such that the bump bonds 86 disposed thereupon are in correspondence with the bump bonds 86 positioned on the back subassembly 14. The front subassembly 12 and the back subassembly 14 are then brought together causing the bump bonds 86 that are in correspondence to become permanently mounted or bonded to one another. A spacing gap 190 exists between the rear surface 65 of the back contact layer 62 and the forward surface 144 of the back mirror 140. This gap 190 may be altered as discussed hereinbelow to effectively change the output wavelength of the light emitted from the tunable laser assembly 10. Once assembled, the front subassembly 12 and the back subassembly 14 are separated by the distance the bump bonds 86 each extend. This distance ensures that the various electrodes do not come into contact where such contact is not warranted.

Operation of the tunable laser assembly 10 includes the application of a voltage between the front electrode 80 and the back electrode 84. The proper voltage applied therebetween will cause the active region to emit light from the rear surface 65 of the back contact layer 61. The light will pass through the optical aperture 62 prior to exiting the rear surface 65, and as such the light will have a cross sectional area smaller than the cross sectional area of the back mirror 140.

Application of a voltage to the back mirror electrode 180 will cause the back mirror 140 to move in a direction away from the back contact layer 61. By applying a voltage to the back mirror electrode 180 an attractive force is established between the front contact layer 120 and the back contact layer 100. This, consequently changes the size of the gap 190 which results in light of a selected wavelength begin reflected from the back mirror 140. As such, the tunable VCSEL assembly 10 is tuned by varying the size of the gap 190 between the rear surface 65 of the back contact layer 61 and the forward surface 144 of the back mirror 140 through application of a voltage between the back mirror electrode 180 and the back contact layer 100.

In a second preferred embodiment of the back subassembly 200 a silicon substrate 210 is preferably used. An n-type layer 212 of silicon is formed upon the substrate 210 and upon the n-type layer; a p-type layer 213 of Si is formed using diffusion, which is well known to those skilled in the art. A sacrificial layer 214, preferably SiO₂, rests or abuts the p-type layer 213. The sacrificial layer 214 may alternatively be formed from another oxide, a dielectric in general, or another semiconductor each of which are preferably matched to the coefficient of thermal expansion of the n-type and p-type layers 212, 213. Just as in the first preferred embodiment, all of the other elements comprising the back subassembly 200 are included herewith. Channeled apertures (not shown) are formed in the sacrificial layer 214. Using doping selective etch, a gap region 216 is generated by underetching the p-type layer 213. The gap region 216 is configured the same as the gap region 130 in the first preferred embodiment. Application of a voltage to the back mirror electrode 180 will cause the back mirror 140 to move in a direction towards the n-type layer 212. By applying a voltage between the back mirror electrode 180 and the n-type layer 212, an attractive force is established between the sacrificial layer 214 and the n-type layer 212.

Alternatively, thermal energy may be applied to the electrode 180 to cause thermal expansion of the sacrificial layer 214. As such, the dissipation of the thermal energy laterally across the sacrificial layer 214 and the coefficient of thermal expansion of the sacrificial layer 214 will cause the sacrificial layer to buckle upwardly, thus moving the mirror 140 towards the back contact layer 61.

In a third preferred embodiment of the back subassembly 300 in accordance with the present invention a SOI substrate 310 is preferably used. An n-type layer 312 of silicon is formed upon the substrate 310 and upon the n-type layer 312, several alternating layers, preferably six, of a p-type layer 314, preferably formed from doped Si, and a sacrificial layer 316, preferably formed from SiO₂ are interleaved.

Channels are provided for in each of the alternating p-type layer 314 and sacrificial layer 316 such that material may be under etched from each sacrificial layer 316 defining an air gap 318. Just as in the first preferred embodiment, all of the other elements comprising the back subassembly 320 are included herewith. Application of a voltage to a back mirror electrode 380, which extends through each p-type layer 314 will cause the integrated mirror 340 to move in a direction towards the back contact layer 61. By applying a voltage to the back mirror electrode 180 an attractive force is established between integrated mirror 340 and the back contact layer 61.

The foregoing description of a preferred embodiment of the invention has been presented for purposes of illustration and description. It is not intended to be exhaustive or to limit the invention to the precise forms disclosed. Obviously, many modifications and variations will be apparent to practitioners skilled in this art. It is intended that the scope of the invention be defined by the following claims and their equivalents.

What is claimed is:

1. A tunable laser assembly, comprising:
a front subassembly;
a back subassembly; and
wherein said front subassembly is permanently bonded to said back subassembly and wherein said front subassembly comprises a back contact layer.

2. The assembly of claim 1, wherein the back contact layer comprises a tunnel junction.

3. The assembly of claim 1, wherein the back contact layer further comprises an optical aperture.

4. The assembly of claim 1, wherein the back contact layer further comprises an electrical aperture.

5. The assembly of claim 1 wherein the back contact layer comprises a funnel area.

6. The assembly of claim 1 wherein the back contact layer comprises a funnel area.

7. The assembly of claim 4 wherein the optical aperture and the electrical aperture have substantially the same configuration.

8. The assembly of claim 1 wherein the back contact layer further comprises an altered depth section.

9. The assembly of claim 8 wherein the altered depth section comprises an index step.

10. The assembly of claim 9 wherein the altered depth section comprises a micro-lens.

11. The assembly of claim 10 wherein the index-step comprises a micro-lens.

12. The assembly of claim 8 wherein the altered depth section comprises a micro-lens.
